(19) United States
(12) Patent Application Publication
(10) Pub. No.: US 2017/0186630 A1
(43) Pub. Date: Jun. 29, 2017

(54) SUBSTRATE MACHINING APPARATUS

(71) Applicant: Shenzhen China Star Optoelectronics Technology Co., Ltd., Shenzhen, Guangdong (CN)

(72) Inventor: Huping JIA, Shenzhen, Guangdong (CN)

(21) Appl. No.: 13/983,644

(22) PCT Filed: Jun. 29, 2013
(86) PCT No.: PCT/CN13/78512

§ 371 Date: Aug. 5, 2013

(30) Foreign Application Priority Data
May 10, 2013 (CN) 201310173579.7

(51) Int. Cl. H01L 21/677; H01L 21/673; H01L 21/67; H01L 21/683

(52) U.S. Cl. CPC H01L 21/677; H01L 21/683; H01L 21/673; H01L 21/67011; H01L 21/304

(57) ABSTRACT

The present invention discloses a substrate machining apparatus, which comprises a clamping means for clamping the substrate and a supporting means for supporting the substrate, wherein both the clamping means and the supporting means comprise a driver for providing driving force. The substrate hold by the clamping means will move synchronously with respect to the supporting means. There is no relative displacement substantially between the substrate and the supporting means.

### FIELD OF THE INVENTION

The present invention relates to the manufacturing technology of liquid crystal displays, and more particularly to a substrate machining apparatus.

### BACKGROUND OF THE INVENTION

Nowadays, LCD (liquid crystal display) TV, PC, Monitors, display devices are widely used. It is necessary to machine the substrate of LCD modules by laser or the like. For example, in the manufacturing process of thin film transistor (TFT), it is necessary to scribe the substrate. In traditional way, the substrate (or strip) is clamped by a chuck, and then the substrate is put on several stationary rollers for positioning. In particular, as shown in FIG. 4, the process comprises the steps of: First tool setting (step S1)→First cutting (step S2)→First tool retracting (step S3)→Second tool setting (step S34)→Second cutting (step S4)→Second tool retracting (step S5). In such way, between the step of cutting and consequent tool setting, there is a step of tool retracting. Although the step of tool retracting will improve cutting precision, it is time consuming.

### SUMMARY OF THE INVENTION

The present invention provides a substrate machining apparatus to solve the mentioned problem above.

The present invention is realized in such a way that: a substrate machining apparatus, comprising a clamping means for clamping the substrate and a supporting means for supporting the substrate, wherein both the clamping means and the supporting means comprise a driver for providing driving force, such that the clamping means and the supporting means move simultaneously.

According to an embodiment disclosed herein, the clamping means comprises a chuck and a first motor for driving the chuck.

According to another embodiment disclosed herein, the first motor is a linear servo motor.

According to another embodiment disclosed herein, the supporting means comprises a synchronous belt conveyor and a second motor for driving the synchronous belt conveyor.

According to another embodiment disclosed herein, the second motor is a stepping motor.

According to another embodiment disclosed herein, the synchronous belt conveyor comprises two pulleys and a synchronous belt passing around the two pulleys.

According to another embodiment disclosed herein, the width of the synchronous belt is equal to the width of the substrate.

According to another embodiment disclosed herein, the substrate machining apparatus further comprises a controller for controlling the driver of the clamping means and the driver of the supporting means such that the clamping means and the supporting means move synchronously.

According to another embodiment disclosed herein, the substrate is a glass substrate.

According to another embodiment disclosed herein, the substrate is a glass substrate for liquid crystal displays.

According to another embodiment disclosed herein, the substrate machining apparatus further comprises a machining tool for scribing the substrate.

According to another embodiment disclosed herein, the machining tool is a cutting tool.

According to yet another embodiment disclosed herein, the machining tool is a laser-beam cutting head.

According to the present invention, a substrate machining apparatus comprises a clamping means for clamping the substrate and a supporting means for supporting the substrate, wherein both the clamping means and the supporting means comprise a driver for providing driving force, the substrate hold by the clamping means can be controlled to move simultaneously with respect to the supporting means. There is no relative displacement substantially between the substrate and the supporting means.

For more clearly and easily understanding above content of the present invention, the following text will take a preferred embodiment of the present invention with reference to the accompanying drawings for detail description as follows.

### BRIEF DESCRIPTION OF THE DRAWINGS

The drawings described herein are for illustration purposes only and are not intended to limit the scope of the present disclosure in any way.

FIG. 1 is a schematic view of the substrate machining apparatus according to an embodiment of the present invention;

FIG. 2 is the schematic electrical control diagram of the substrate machining apparatus in FIG. 1;

FIG. 3 is schematic flowchart of the substrate machining process using the substrate machining apparatus in FIG. 1; and

FIG. 4 is schematic flowchart of traditional substrate machining process.

### DETAILED DESCRIPTION OF PREFERRED EMBODIMENTS

The following detailed description of every embodiment with reference to the accompanying drawings is used to exemplify a specific embodiment, which may be carried out in the present invention. Directional terms mentioned in the present invention, such as “top”, “bottom”, “front”, “rear”, “left”, “right”, “up”, “down”, “inside”, “outside”, “side” etc., are only used with reference to the orientation of the accompanying drawings. Therefore, the used directional terms are intended to illustrate, but not to limit, the present invention. Also the following description is merely exemplary in nature and is not intended to limit the present disclosure, application, or uses. Besides, the term “machining” used herein means to shape, cut, scribe or remove (excess material) from (a workpiece) using a machine tool.

According to the present invention, the substrate machining apparatus comprises a clamping means 300 for clamping (holding) the substrate 100 and a supporting means 200 for supporting the substrate 100. Both the clamping means 300 and the supporting means 200 comprise a driver for providing driving force, such that the clamping means and the supporting means move simultaneously. The clamping means 300 comprises a driver for providing driving force. The supporting means 200 also comprises a driver for providing driving force. The clamping means 300 and the supporting means 200 are driven to move synchronously (simultaneously) by means of respective drivers. The substrate 100 may be a glass substrate. In this embodiment, the substrate 100 is a glass substrate for liquid crystal displays.

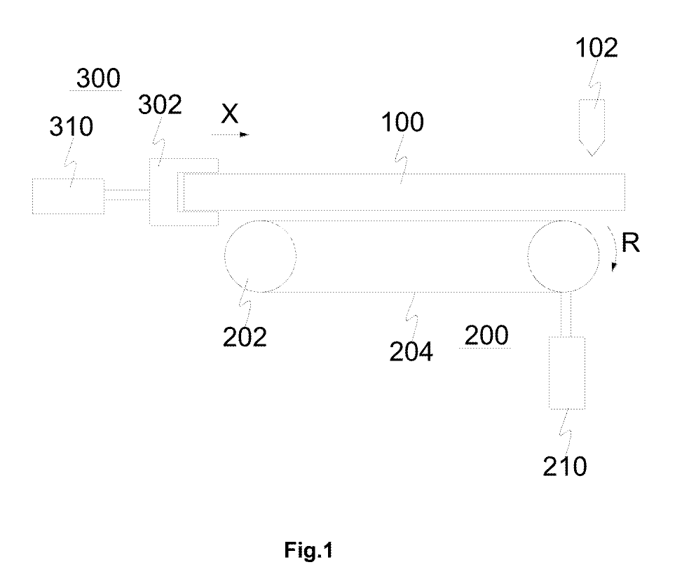

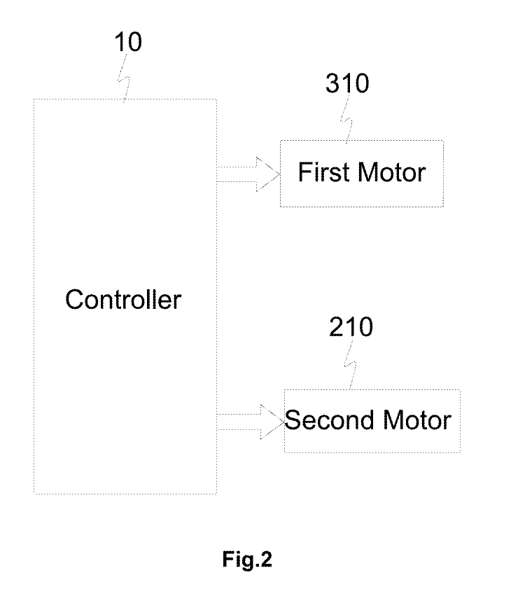

As shown in FIG. 1 and FIG. 2, the clamping means 300 comprises a chuck 302 and a first motor 310 for driving the chuck 302 to move. The supporting means 200 comprises a synchronous belt conveyor and a second motor 210 for driving the synchronous belt conveyor. To be specific, the synchronous belt conveyor comprises two pulleys 202 and a synchronous belt 204 passing around the two pulleys 202. In the embodiment, the substrate machining apparatus comprises a machining tool 102 for scribing the substrate 100. In the beginning of the machining process, the machining tool 102 will be aligned with a desired position on the substrate 100 (tool setting). The machining tool may be a cutting tool or a laser-beam cutting head.

As described above, the synchronous belt conveyor comprises two pulleys 202 and a synchronous belt 204, as shown in FIG. 1. The width of the synchronous belt 204 is preferably equal to the width of the substrate 100. In this way, the substrate 100 can be steadily supported. The pulleys 202 may rotate along the close wise direction R. The substrate 100 may move linearly along the longitudinal direction X.

In the embodiment, the first motor 310 is a linear servo motor; and the second motor 210 is a stepping motor.

As shown in FIG. 1 and FIG. 2, the substrate machining apparatus further comprises a controller 10 for controlling the driver (i.e. first motor 310) of the clamping means 300 and the driver (i.e. second motor 210) of the supporting means 200 such that the clamping means 300 and the supporting means 200 move synchronously and linearly (for example, along the longitudinal direction X). When the pulleys 202 rotate along the close wise direction R, the chuck 302 and the substrate 100 are driven by the first motor 310 to move along the longitudinal direction X, such that there is no relative displacement substantially between the substrate 100 and the synchronous belt 204.

According to the present invention, both the clamping means 300 and the supporting means 200 comprise a driver for providing driving force, the substrate 100 hold by the chuck 302 will move synchronously with respect to the synchronous belt 204. There is no relative displacement substantially between the substrate 100 and the synchronous belt 204. The substrate 100 is stationary with respect to the synchronous belt 204. Also, the transportation precision can be improved. In a preferred embodiment, the transportation precision can be improved and the tolerance of relative displacement is about ±40 um.

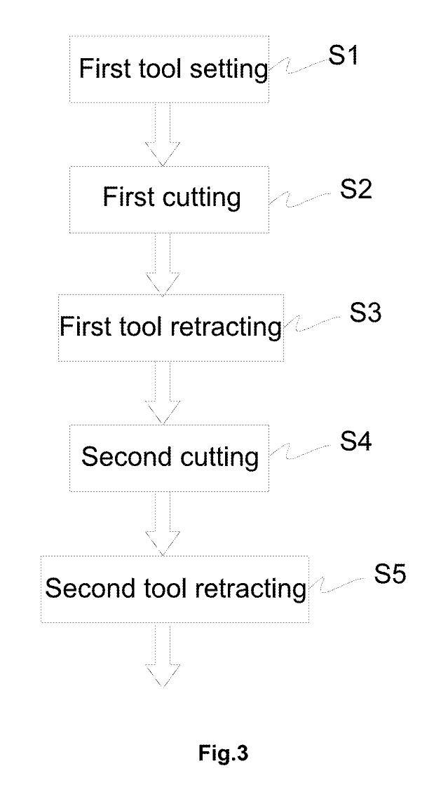

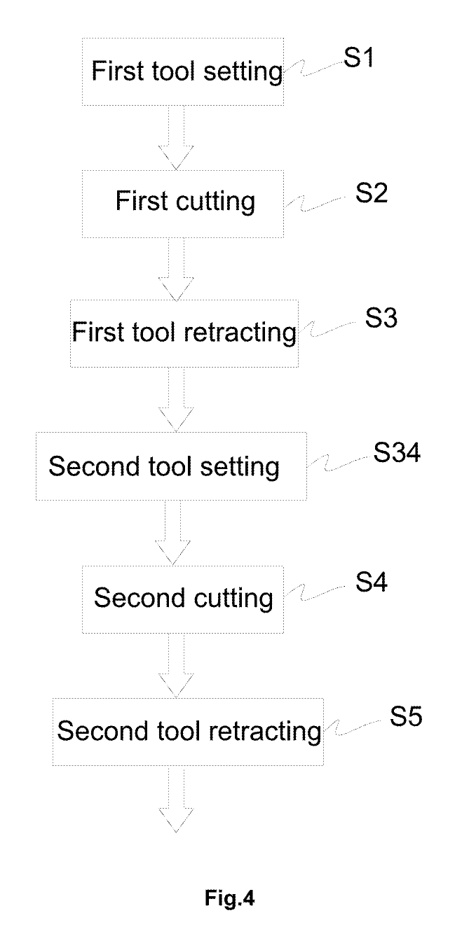

As shown in FIG. 3, which shows the substrate machining process using the substrate machining apparatus in FIG. 1, the substrate machining process comprises the steps of: First tool setting (step S1)→First cutting (step S2)→First tool retracting (step S3)→Second cutting (step S4)→Second tool retracting (step S5). Compared with the traditional process shown in FIG. 4, the second tool setting (step S34) can be omitted. Since in the substrate machining process, the substrate 100 is stationary with respect to the synchronous belt 204, there is no need to execute second tool setting and consequent tool setting steps. Hence, the machining time can be saved, and thus the productivity can be improved.

According to the present invention, both the clamping means 300 and the supporting means 200 comprise a driver for providing driving force, the substrate 100 hold by the chuck 302 will move synchronously with respect to the synchronous belt 204, the transportation precision can be improved. Moreover, there is only need to perform first tool setting step at the beginning, and the tool setting step afterwards can be omitted, the machining time can be saved, and thus the productivity can be improved.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A substrate machining apparatus, comprising a clamping means for clamping the substrate and a supporting means for supporting the substrate, wherein both the clamping means and the supporting means comprise a driver for providing driving force.

2. The substrate machining apparatus of claim 1, wherein the clamping means comprises a chuck and a first motor for driving the chuck.

3. The substrate machining apparatus of claim 2, wherein the first motor is a linear servo motor.

4. The substrate machining apparatus of claim 1, wherein the supporting means comprises a synchronous belt conveyor and a second motor for driving the synchronous belt conveyor.

5. The substrate machining apparatus of claim 4, wherein the second motor is a stepping motor.

6. The substrate machining apparatus of claim 4, wherein the synchronous belt conveyor comprises two pulleys and a synchronous belt passing around the two pulleys.

7. The substrate machining apparatus of claim 6, wherein the width of the synchronous belt is equal to the width of the substrate.

8. The substrate machining apparatus of claim 1, wherein the substrate machining apparatus further comprises a controller for controlling the driver of the clamping means and the driver of the supporting means such that the clamping means and the supporting means move synchronously.

9. The substrate machining apparatus of claim 1, wherein the substrate is a glass substrate.

10. The substrate machining apparatus of claim 1, wherein the substrate is a glass substrate for liquid crystal displays.

11. The substrate machining apparatus of claim 1, wherein the substrate machining apparatus further comprises a machining tool for scribing the substrate.

12. The substrate machining apparatus of claim 1, wherein the machining tool is a cutting tool.

13. The substrate machining apparatus of claim 1, wherein the machining tool is a laser-beam cutting head.
